(19) United States
(12) Patent Application Publication
(10) Pub. No.: US 2006/0175669 A1
(43) Pub. Date: Aug. 10, 2006

(54) Semiconductor device including FinFET having metal gate electrode and fabricating method thereof

(75) Inventors: Sung-min Kim, Incheon Metropolitan City (KR); Dong-won Kim, Seongnam-si (KR); Min-sang Kim, Seoul (KR); Eun-jung Yun, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/339,126

(22) Filed: Jan. 25, 2006

(30) Foreign Application Priority Data
Feb. 5, 2005 (KR) 10-2005-0011018

(51) Int. Cl. H01L 29/76

(52) U.S. Cl. 257/401

(57) ABSTRACT

Provided are a semiconductor device including a FinFET having a metal gate electrode and a fabricating method thereof. The semiconductor device includes: an active area formed in a semiconductor substrate and protruding from a surface of the semiconductor substrate; a fin including first and second protrusions formed of a surface of the active area and parallel with each other based on a central trench formed in the active area and using upper surfaces and sides of the first and second protrusions as a channel area; a gate insulating layer formed on the active area including the fin; a metal gate electrode formed on the gate insulating layer; a gate spacer formed on a sidewall of the metal gate electrode; and a source and a drain formed in the active area beside both sides of the metal gate electrode. Here, the metal gate electrode comprises a barrier layer contacting the gate spacer and the gate insulating layer and a metal layer formed on the barrier layer.

### CROSS-REFERENCE TO RELATED PATENT APPLICATION

This application claims the benefit of Korean Patent Application No. 10-2005-0011018, filed on Feb. 5, 2005, in the Korean Intellectual Property Office, the disclosure of which is incorporated herein in its entirety by reference.

### BACKGROUND OF THE INVENTION

1. Field of the Invention

The present invention relates to a semiconductor device and a fabricating method thereof, and more particularly, to a semiconductor device including a Fin Field Effect Transistor (FinFET) and a fabricating method thereof.

2. Description of the Related Art

The integration density of semiconductor devices has been continuously increased to improve the performance of the semiconductor devices and reduce fabricating cost for the semiconductor devices. A technique for reducing feature sizes of the semiconductor devices is required to increase the density of the semiconductor devices.

A Metal-Oxide-Semiconductor Field Effect Transistor (MOSFET) channel length has been shortened in a process of fabricating a semiconductor device to improve the speed and the density of the semiconductor device. However, in this case, a gap between a source and a drain of the semiconductor device is shortened. This is referred to as a short channel effect due in which it is difficult to efficiently inhibit potentials of the source and a channel from being affected by a potential of the drain. That is, the characteristic of the semiconductor device as an active switch is degraded. A conventional MOSFET in which a channel is formed parallel with a surface of a semiconductor is a planar channel device. In such a device, it is difficult to reduce the size of the conventional MOSFET. Also, in a planar device, it is difficult to inhibit the short channel effect from occurring.

In a FinFET, a fin-shaped active area is formed and then a gate encloses both sides and an upper surface of the fin-shaped active area to form a tri-gate structure so as to use a channel having a 3-dimenstional structure instead of a planar structure. Unlike a planar MOSFET, in such a FinFET, a channel is formed perpendicular to a surface of a substrate so as to reduce a size of the semiconductor device. Also, a junction capacitance of a drain is greatly reduced so as to reduce a short channel effect. To use these advantages, attempts to replace existing MOSFETs with FinFETs have been made. For example, U.S. Pat. Nos. 6,391,782 and 6,664,582 disclose such FinFETs.

However, in conventional FinFETs, a threshold voltage is low due to a thin body effect. Thus, it is difficult to operate CMOS circuits without degrading the performance of the FinFETs. To solve these problems, there has been suggested gate work function engineering such as a dual metal gate process, a single metal gate process of injecting ions into a gate, and a gate process of making the whole structure silicide. However, the work function engineering is difficult to be realized in the operation of CMOS devices.

### SUMMARY OF THE INVENTION

The present invention provides a semiconductor device including a FinFET having a threshold voltage appropriate for low voltage, high-performance driving and a fabricating method thereof.

According to an aspect of the present invention, there is provided a semiconductor device including: an active area formed in a semiconductor substrate and protruding from a surface of the semiconductor substrate; a fin-shaped structure including first and second protrusions formed in a surface of the active area and parallel with each other based on a central trench formed in the center of the active area and using upper surfaces and sides of the first and second protrusions as a channel area; a gate insulating layer formed on the active area including the fin; a metal gate electrode formed on the gate insulating layer; a gate spacer formed on a sidewall of the metal gate electrode; and a source and a drain formed in the active area beside both sides of the metal gate electrode. Here, the metal gate electrode comprises a barrier layer contacting the gate spacer and the gate insulating layer and a metal layer formed on the barrier layer.

According to another aspect of the present invention, there is provided a method of fabricating a semiconductor device, including: defining an active area protruding from a surface of a semiconductor substrate; etching a central portion of the active area to form a central trench so as to form a fin including first and second protrusions formed of a surface of the active area and parallel with each other based on the central trench and using upper surfaces and sides of the first and second protrusions as a channel area; forming a gate insulating layer on the active area including the fin; forming a dummy gate electrode on the gate insulating layer; forming a gate spacer on a sidewall of the dummy gate electrode; forming a source and a drain in the active area beside both sides of the dummy gate electrode; depositing and planarizing an insulating layer on the semiconductor substrate so as to expose an upper surface of the dummy gate electrode; removing the dummy gate electrode; and forming a metal gate electrode in an area in which the dummy gate electrode is removed.

According to still another aspect of the present invention, there is provided a method of fabricating a semiconductor device, including: forming an active area hared mask on a semiconductor substrate; etching the semiconductor substrate using the active area hard mask as an etching mask to define an active area protruding from a surface of the semiconductor substrate and to form a trench enclosing the active area; isotropic etching the active area hard mask to form a hard mask pattern exposing an edge of the active area; filling the trench with a gap fill oxide layer and planarizing the gap fill oxide layer using the hard mask pattern as a planarization ending point; patterning the gap fill oxide layer and the hard mask pattern in a line type to form a dummy pattern including at least one channel area definition pattern in the center; depositing a blocking layer on the dummy pattern and planarizing the blocking layer using the channel area definition pattern as a planarization ending point; removing the channel area definition pattern exposed during the planarization of the blocking layer to form an opening exposing a surface of the active area; etching the active area below the opening to form a central trench in a portion to be used as fin channel; recessing the blocking layer and the gap fill oxide layer to form an isolation layer around the exposed portion of the active area and exposing a fin comprising first and second protrusions formed of a surface of the semiconductor substrate between the central trench and the isolation layer and parallel with each other based on the central trench and using upper surfaces and sides of the first and second protrusions; forming a gate insulating layer on the active area including the fin; forming a dummy gate electrode on the gate insulating layer; forming a gate spacer on a sidewall of the dummy gate electrode; forming a source and a drain in the active area beside both sides of the dummy gate electrode; depositing and planarizing an insulating layer on the semiconductor substrate to expose an upper surface of the dummy gate electrode; removing the dummy gate electrode; and forming a metal gate electrode in an area in which the dummy gate electrode is removed.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a layout diagram of a semiconductor device fabricated using methods of fabricating a semiconductor device according to embodiments of the present invention.

FIGS. 2 through 10 and 12 through 14 are views illustrating intermediate structures of a semiconductor device having a layout as shown in FIG. 1 in a method of fabricating the semiconductor device according to an embodiment of the present invention.

FIG. 11 is a cross-sectional view taken along direction Y shown in FIG. 10.

FIG. 15 is a cross-sectional view taken along direction Y shown in FIG. 14.

FIG. 16 is a cross-sectional view of a semiconductor device according to another embodiment of the present invention.

FIG. 17 is a view illustrating an intermediate structure of a semiconductor device in a method of fabricating the semiconductor device according to still another embodiment of the present invention.

FIG. 18 shows a scanning electron microscopy (SEM) image and a transmission electron microscope (TEM) image of a FinFET static random access memory (SRAM) cell transistor having a 65 nm-TiN/W gate electrode.

FIG. 19 is a graph showing drain currents ID and gate voltages V_{G} of a FinFET having a TiN/W electrode according to the present invention, a conventional FinFET having a polysilicon gate electrode, and a conventional planar MOSFET having a polysilicon gate electrode.

FIG. 20 is a graph showing driving currents of a FinFET having a TiN/W electrode according to the present invention, a conventional FinFET having a polysilicon gate electrode, and a conventional planar MOSFET having a polysilicon gate electrode.

FIG. 21 is a graph showing a counter doping effect in a method of fabricating a semiconductor device according to an embodiment of the present invention.

### DETAILED DESCRIPTION OF THE INVENTION

First Embodiment

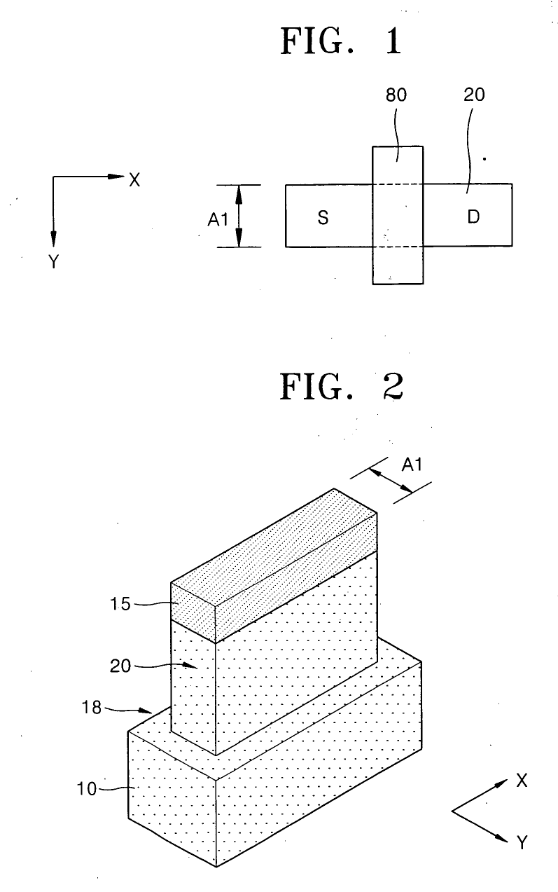

FIG. 1 is a layout view of a semiconductor device to be fabricated using methods of fabricating a semiconductor device according to first through third embodiments of the present invention. Referring to FIG. 1, an active area 20 is defined to be extended in one direction, for example, in direction X and has a predetermined line width A1 in direction Y orthogonal to the direction X. A metal gate electrode 80 is formed above the active area 20 to be extended in the direction Y. A source S and a drain D are formed in the active area 20 beside both sides of the metal gate electrode 80.

As shown in FIG. 1, a width of a contact area formed in the source S and the drain D is greater than a width (a length of a cross-section in the direction X) of the metal gate electrode 80. In the present invention, such a layout can be designed so as to solve a limit to securing a source and/or drain contact area, the limit caused by patterning. However, a layout of a semiconductor device according to the present invention is not necessarily confined to the layout shown in FIG. 1. For example, the width of the metal gate electrode 80 may be greater than the width of the contact area in the source S and the drain D.

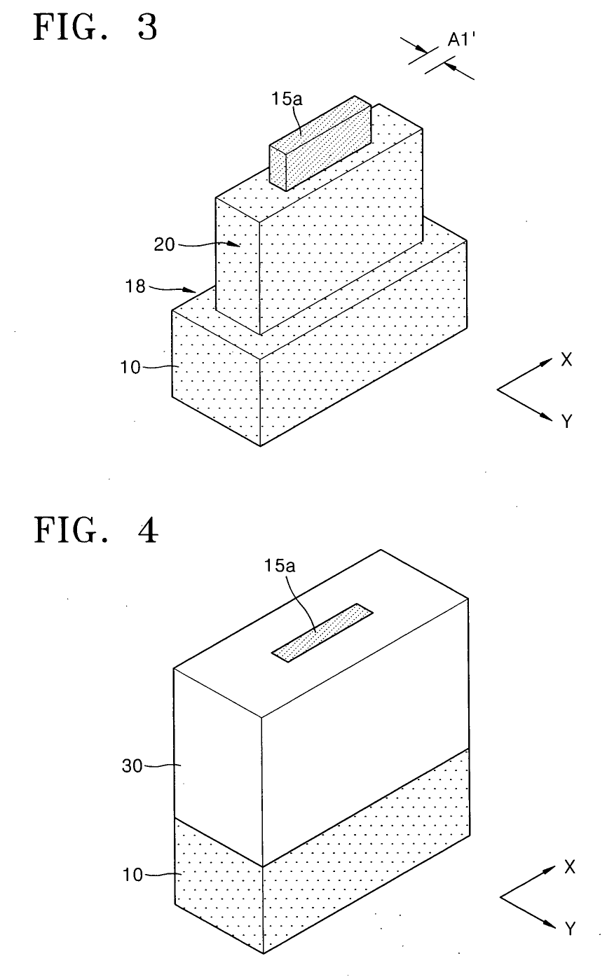

FIGS. 2 through 9 are perspective views illustrating a method of fabricating a semiconductor device having a layout as shown in FIG. 1. Intermediate structures formed in steps of a process are shown in FIGS. 2 through 9.

Referring to FIG. 2, an active area hard mask 15 is formed above a semiconductor substrate 10 such as p-type bulk silicon wafer so as to define an active area 20 as shown in FIG. 1. Besides the p-type bulk silicon wafer, the semiconductor substrate 10 may be a Silicon-On-Insulator (SOI) substrate, a Silicon Germanium-On-Insulator (SGOI) substrate, or silicon germanium (SiGe) wafer. The active area hard mask 15 is formed by depositing an insulating layer such as a silicon nitride layer above the semiconductor substrate 10 to a thickness between 800 Å and 2000 Å using Plasma Enhanced-Chemical Vapor Deposition (PE-CVD) or Low Pressure-CVD (LP-CVD) and then patterning the insulating layer in a predetermined shape. As shown in FIG. 2, the active area hard mask 15 extends in the direction X SO as to have a predetermined line width A1 in the direction Y. If the occurrence of stress between the active area hard mask 15 and the semiconductor substrate 10 is an issue, an oxide layer may be further formed between the active area hard mask 15 and the semiconductor substrate 10 using a thermal oxidation method.

The semiconductor substrate 10 may be etched using the active area hard mask 15 as an etching mask to define the active area 20 protruding from a surface of the semiconductor substrate 10 and form a trench 18 enclosing the active area 20. A depth of the trench 18 may be within a range between 1000 Å and 3000 Å. The semiconductor substrate 10 may be dry etched using a mixture of a halogen gas such as HBr or Cl₂ and oxygen.

Referring to FIG. 3, the active area hard mask 15 is isotropically etched to form a hard mask pattern 15a exposing the edge of the active area 20. Here, the isotropic etching is blanket etching not using an etching mask by which the active area hard mask 15 is etched. This is also referred to as pull back. If the active area hard mask 15 is formed of a silicon nitride layer, the active area hard mask 15 may be wet etched using phosphoric acid (H₃PO₄) or may be dry etched using plasma. As a result, the hard mask pattern 15a, having narrower line widths in the directions X and Y than the active area hard mask 15, is formed. In a case where the line width of the hard mask pattern 15a in the direction Y is A1′, a difference A1-A1′ between the line width A1 of the active area hard mask 15 and the line width A1′ of the hard mask pattern 15a is determined as a width of a fin or fin-shaped structure to be used as a channel of the device. As the line width A1′ of the hard mask pattern 15a is made to be more narrow, the width of the fin is increased. An isotropic etching (pull back) time is appropriately adjusted to adjust the width of the fin.

Referring to FIG. 4, the trench 18 is filled with an insulating material, for example, a gap fill oxide layer 30, and then the gap fill oxide layer 30 is planarized using the hard mask pattern 15a as a planarization ending point. The gap fill oxide layer 30 may be deposited using High Density Plasma (HDP)-CVD and planarized using CMP or blanket etching.

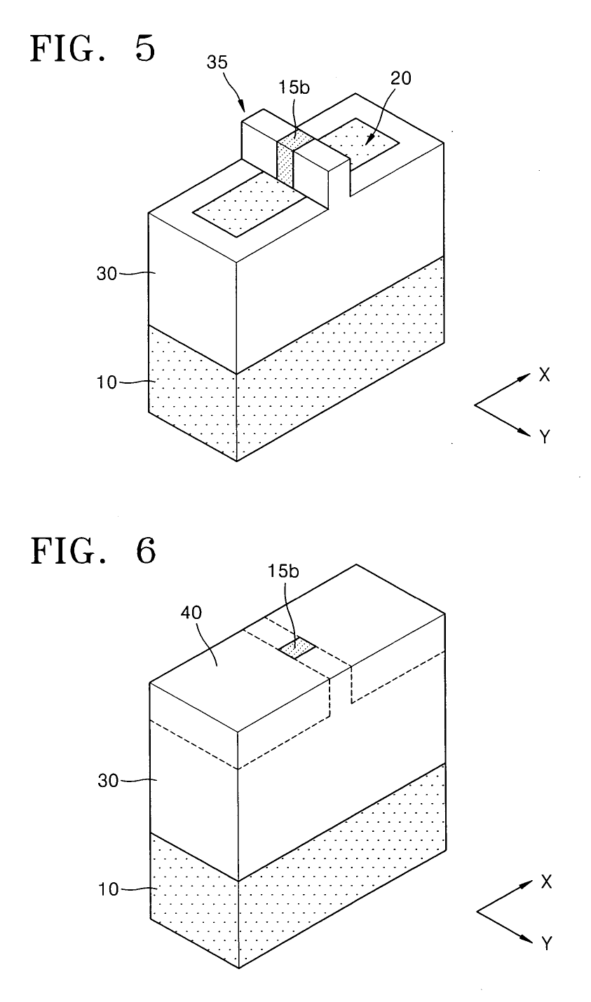

Referring to FIG. 5, the gap fill oxide layer 30 and the hard mask pattern 15a are patterned to form a dummy pattern 35 in a position of the metal gate electrode 80 extending in the direction Y as shown in FIG. 1. Here, the gap fill oxide layer 30 and the hard mask pattern 15a may be patterned using etching under the condition of the same etching selectivity or similar etching selectivities. Due to the formation of the dummy pattern 35, most portions of the hard mask pattern 15a are removed, a channel area definition pattern 15b is formed in the center of the active area 20, and a portion of the active area 20 below the dummy pattern 35 is exposed.

Referring to FIG. 6, a blocking layer 40 such as a silicon oxide layer is deposited on the dummy pattern 35 and planarized using the channel area definition pattern 15b as a planarization ending point. Here, the blocking layer 40 may be deposited adopting HDP-CVD used for depositing the gap fill oxide layer 30. Also, the blocking layer 40 may be planarized using CMP or blanket etching. Since the blocking layer 40 and the gap fill oxide layer 30 are the same or similar type of oxide layers, an interface between the blocking layer 40 and the gap fill oxide layer 30 does not substantially exist. This virtual interface is marked with dotted lines in FIG. 6.

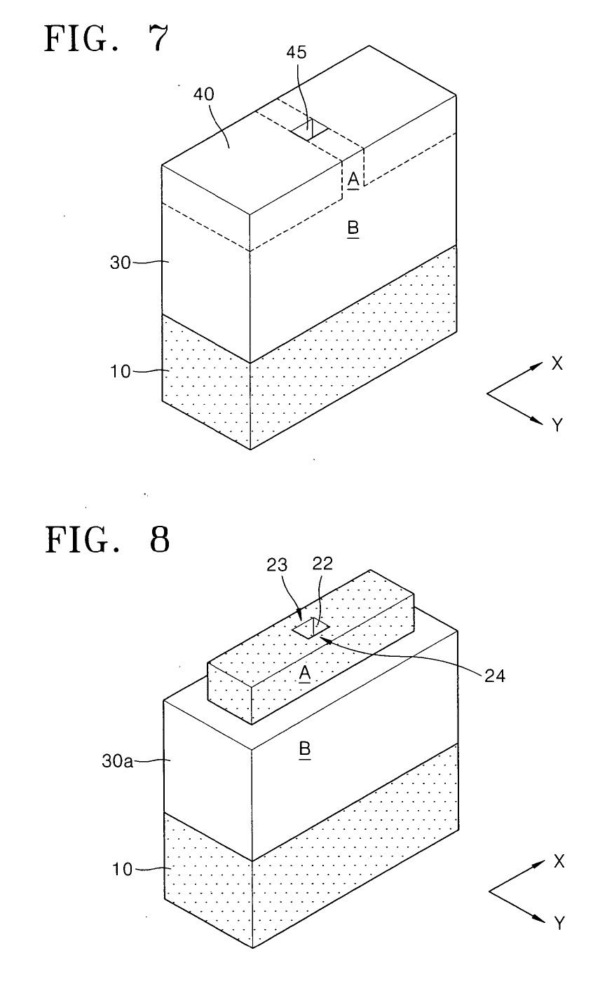

Referring to FIG. 7, the channel area definition pattern 15b exposed in the planarization step described with reference to FIG. 6 is selectively removed with respect to the blocking layer 40, the gap fill oxide layer 30, and the semiconductor substrate 10 using wet or dry etching. The channel area definition pattern 15b formed of a silicon nitride layer may be wet etched using a phosphoric acid strip. As a result, an opening 45 is formed in the position of the channel area definition pattern 15b, and a portion of a surface of the semiconductor substrate 10 below the opening 45, i.e., a portion of the active area 20, is exposed. The active area 20 below the opening 45 is etched using the blocking layer 40 and the gap fill oxide layer 30 as etch masks to define a portion to be used as a fin channel. As previously described, a width of a fin in a cell area is a difference between a line with A1 of the active area 20 in direction Y and a line with A1′ of the hard mask pattern 15a in the direction Y, i.e., a difference A1-A1′ between the line width A1 of the active area hard mask 15 in the direction Y and a line width A1′ of the channel area definition pattern 15b in the direction Y. Here, ions may be implanted into a channel before the active area 20 below the opening 45 is etched to define the portion to be used as the fin channel. However, a conductivity type of impurities implanted into a low portion B of the fin is opposite to a conductivity type of impurities implanted into an upper portion A of the fin. This is referred to as counter doping. Such implantation of opposite conductivity types of impurities may contribute to lowering a threshold voltage without increasing an off-leakage current. Here, the ion implantation is performed perpendicular to the semiconductor substrate 10 without an angle of inclination.

Referring to FIG. 8, the blocking layer 40 and the gap fill oxide layer 30 are recessed to the same depth as that of the channel. Here, the blocking layer 40 and the gap fill oxide layer 30 may be recessed adopting wet etching using an HF diluted solution or a buffered oxide etchant (BOE). As a result, an isolation layer 30a is formed around the exposed portion of the active area 20. A central trench 22 is formed in the active area 20 around the fin channel by etching through the opening 45. Thus, first and second protrusions 23 and 24 formed on or in the surface of the semiconductor substrate 10 are exposed in the active area 20 between the central trench 22 and the isolation layer 30a. Upper surfaces and sides of the first and second protrusions 23 and 24 provide a channel area having a 3-dimensional structure. The protrusions 23 and 24 are parallel with each other and have the central trench 22 disposed between them.

In a case where the ions are not implanted into the channel in the step described with reference to FIG. 7, the ions may be implanted into the channel after the fin is exposed in the step described with reference to FIG. 8. Here, opposite conductivity types of impurities may be implanted into the upper and lower portions B and A of the fin. In this case, inclination ion implantation may be performed.

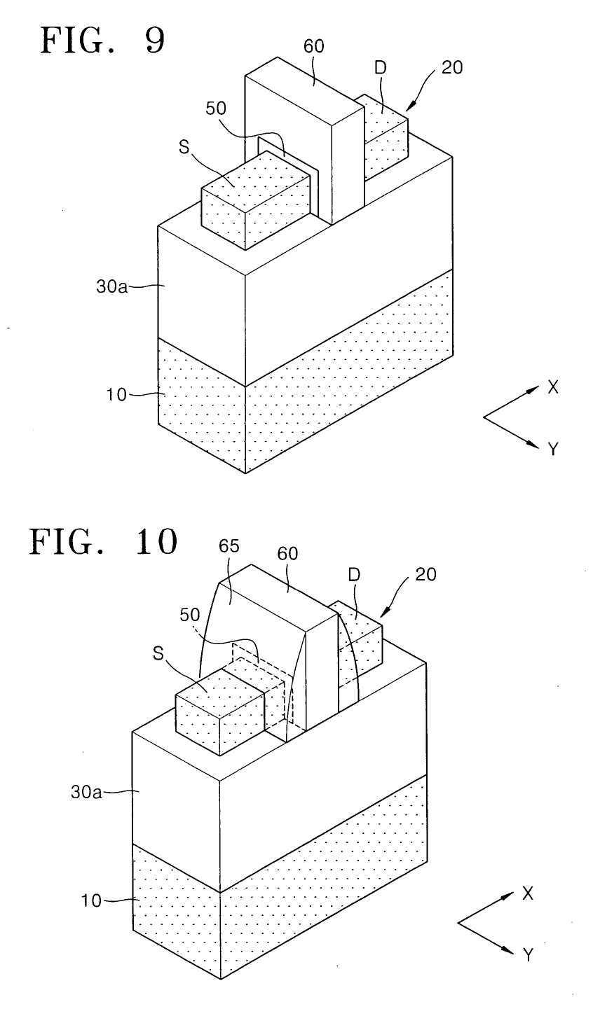

Referring to FIG. 9, a gate insulating layer 50 is formed on the active area 20 to a thickness of 10 Å to 70 Å. The gate insulating layer 50 may be formed by growing a silicon oxide layer using a thermal oxidation method. Alternatively, the insulating layer 50 may be formed by depositing or coating an insulating material, for example, a silicon oxide layer, a hafnium oxide layer, a zirconium oxide layer, an aluminum oxide layer, a silicon nitride layer, or a silicon oxide nitride layer using Atomic Layer Deposition (ALD), CVD, Plasma Enhanced-ALD (PE-ALD), or PE-CVD. Next, a dummy gate electrode 60 is formed on the insulating layer 50 in the same shape as the metal gate electrode 80 shown in FIG. 1. The dummy gate electrode 60 is formed by forming an undoped or doped polysilicon layer and then patterning the undoped or doped polysilicon layer to extend in the direction Y. Here, the dummy gate electrode 60 has the same width as or a greater width than the central trench 22, covers the channel area, i.e., the upper surfaces and the sides of the first and second protrusions 23 and 24, and crosses the channel area. A size of the central trench 22 is determined depending on a size of the opening 45 which is determined depending on a size of the channel area definition pattern 15b. Thus, the size of the channel area definition pattern 15b must be small to increase the areas of the source S and the drain D. In the present embodiment, a width of the dummy gate electrode 60 is greater than a width of the channel area definition pattern 15b.

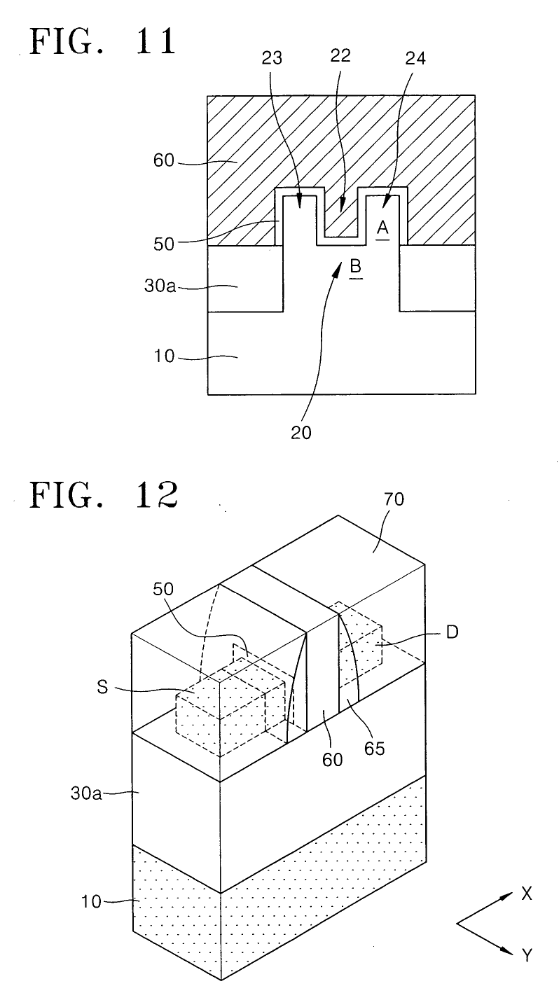

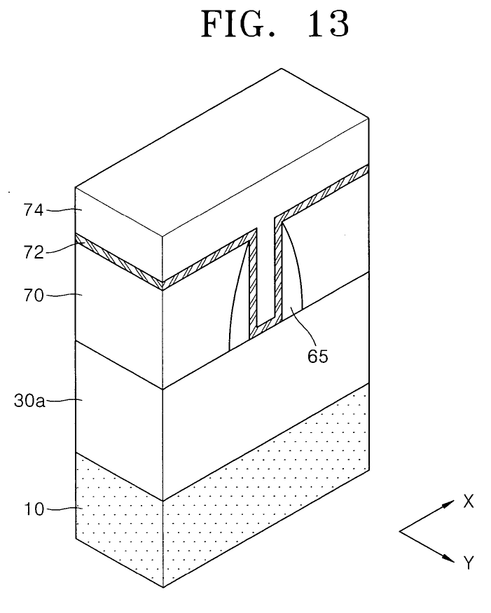

As shown in FIG. 10, a gate spacer 65 is formed at a sidewall of the dummy gate electrode 60. The gate spacer 65 may be formed of a silicon nitride layer. After the active area 20 is implanted with ions adopting a self-alignment method using the dummy gate electrode 60 and the gate spacer 65 and then is thermally treated, the source S and the drain D are formed in the active area 20 beside both sides of the dummy gate electrode 60. Here, in terms of the design of the layout, a width of a contact area (not shown) formed in the source S and the drain D is greater than a width of the dummy gate electrode 60. Thus, the contact area in the source S and the drain D is not limited. The source S and the drain D may be of Lightly Doped Drain (LDD) type. In this case, the gate spacer 65 is formed between high density (E15 cm² level) ion implantation and low density (E12/cm²˜E13/cm² level) ion implantation.

FIG. 11 is a cross-sectional view taken along the direction Y shown in FIG. 10. Since the blocking layer 40 and the gap fill oxide layer 30 are recessed to the same depth as that of the channel in the step described with reference to FIG. 8, the bottom of the central trench 22 is on the same level as a surface of the isolation layer 30a as shown in FIG. 11. Opposite conductivity types of impurities are implanted to the lower and upper portion B and A of the fin.

As shown in FIG. 12, an insulating layer 70 is deposited above the semiconductor substrate 10 and then planarized so as to expose an upper surface of the dummy gate electrode 60. The insulating layer 70 may be formed of an oxide layer deposited using HDP-CVD and then planarized using CMP.

Referring to FIG. 13, the dummy gate electrode 60 is removed. Here, a portion of the gate insulating layer 50 or the whole portion of the gate insulating layer 50 may be removed. In this case, a second gate insulating layer may be formed. A barrier layer 72 is formed of a TiN layer in an area in which the dummy gate electrode 60 is removed. A metal layer 74 is formed of a W layer on the barrier layer 72 so as to completely bury the area in which the dummy gate electrode 60 is removed. Here, the TiN layer and the W layer may be deposited using LP-CVD. However, in the present invention, a combination of the barrier layer 72 and the metal layer 74 is not necessarily limited to TiN/W.

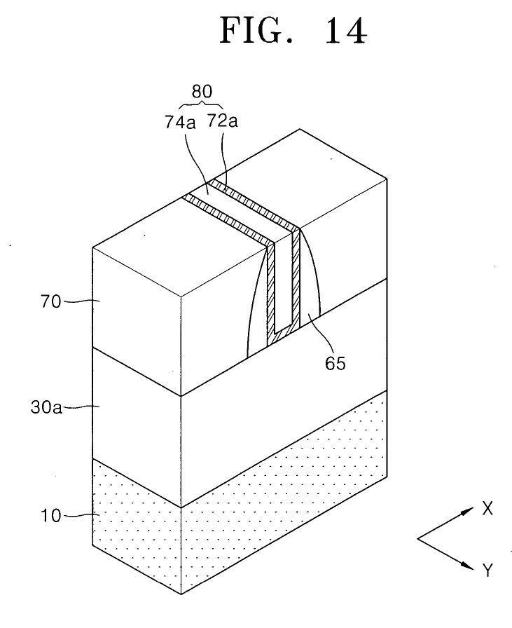

As shown in FIG. 14, the barrier layer 72 and the metal layer 74 are planarized using CMP to complete the metal gate electrode 80 including a barrier layer 72a and a metal layer 74a. In general, it is difficult to pattern a metal gate electrode. However, in the present invention, the metal gate electrode 80 is formed using a damascene method without difficult patterning.

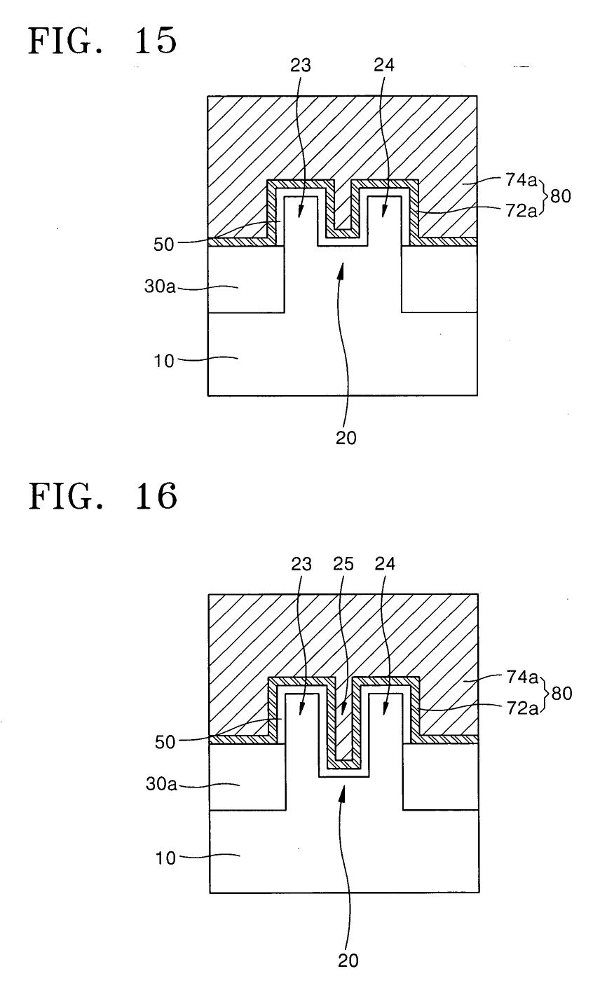

FIG. 15 is a cross-sectional view taken along direction Y shown in FIG. 14. As shown in FIG. 15, the metal gate electrode 80 includes the barrier layer 72a contacting the gate spacer 65 and the gate insulating layer 50 and the metal layer 74a formed on the barrier layer 72a.

As described with reference to FIGS. 1 through 15, a semiconductor device according to the present embodiment includes the semiconductor substrate 10 and the active area 20 formed in the semiconductor substrate 10 and protruding from the surface of the semiconductor substrate 10. The active area 20 is of a line type extending in direction X. In one embodiment, the active area 20 includes the first and second protrusions 23 and 24 formed of the surface of the active area 20 and parallel with each other based on the central trench 22 formed in the center of the active area 20 and the fin using the upper surfaces and the sides of the first and second protrusions 23 and 24 as the channel area.

The gate insulating layer 50 and the metal gate electrode 80 are formed on the active area 20. The metal gate electrode 80 has the same width as the central trench 22, covers the upper surfaces and the sides of the first and second protrusions, and extends in the direction Y.

The source S and the drain D are formed in the active area 20 besides both sides of the metal gate electrode 80. The width of the contact area formed in the source S and the drain D is greater than the width of the metal gate electrode 80. The isolation layer 30a on the same level as the bottom of the central trench 22 is formed around the active area 20. The gate spacer 65 is formed at the sidewall of the metal gate electrode 80, and the metal gate electrode 80 includes the barrier layer 72a contacting the gate spacer 65 and the gate insulating layer 50 and the metal layer 74a on the barrier layer 72a.

As described above, the semiconductor device according to the present embodiment includes a contact area of a source and a drain having a greater width than a width of a channel and a fin having two protrusions based on a central trench in an active area. The formation of the fin having the two protrusions increases the area of the channel, which increases operation speed of the semiconductor device. In a case where a bulk silicon substrate is used, fabricating cost can be reduced more than when an SOI or SGOI substrate is used. Also, problems, such as a floating body effect possible in an SOI or SGOI MOSFET device, a decrease in a breakdown voltage between a drain and a source, and an increase in an off-leakage current, do not occur. If the SOI or SGOI substrate is used, a bottom channel may be prevented from being turned on. If the SGOI or a silicon germanium substrate is used, fast mobility of a material used for the SGOI or the silicon germanium substrate may be used. Also, the semiconductor device includes a metal gate electrode so as to have more many advantages than when including a polysilicon gate electrode.

Second Embodiment

FIG. 16 is a cross-sectional view of a semiconductor device in direction Y according to a second embodiment of the present invention. The same reference numerals as those in FIGS. 2 through 15 denote like elements, and thus description of theses elements will not be repeated.

The present embodiment is a modified example of the first embodiment.

The steps described with reference to FIGS. 2 through 6 are performed as in the first embodiment. When the step described with reference to FIG. 7 is performed, the semiconductor substrate 10 below the opening 45 is etched to a deeper depth than in the first embodiment to define a portion to be used as the fin channel. The blocking layer 40 and the gap fill oxide layer 30 are recessed as described with reference to FIG. 8. However, the gap fill oxide layer 30 is recessed to a shallower depth than the depth of the channel. The steps described with reference to FIGS. 9 through 15 are performed as in the first embodiment. As a result, the cross-sectional view shown in FIG. 16 is obtained.

As shown in FIG. 16, the central trench 25 is formed to a deeper depth than in the first embodiment, and the blocking layer 40 and the gap fill oxide layer 30 are less recessed than the depth of the channel. Thus, the surface of the isolation layer 30a is lower than the surface of the active area 20 but higher than the bottom of the central trench 25. That is, the central trench 25 is formed to a deeper depth than the surface of the isolation layer 30a. As a result, an effective channel width can be maximized.

Third Embodiment

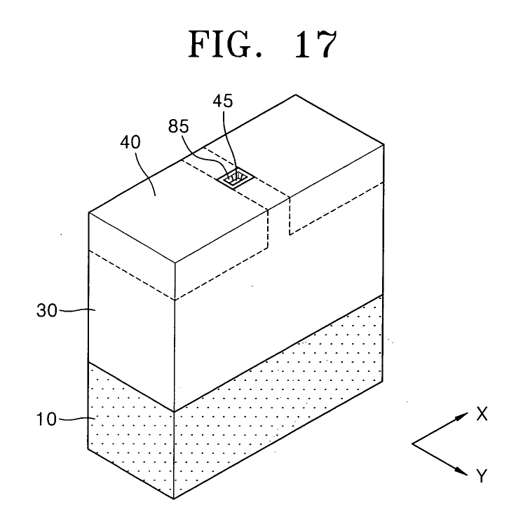

FIG. 17 is a perspective view illustrating a method of fabricating a semiconductor device according to a third embodiment of the present invention. The same reference numerals as those in FIGS. 2 through 7 denote like elements, and thus description of those elements will not be repeated.

The steps described with reference to FIGS. 2 through 6 are performed as in the first embodiment. The channel area definition pattern 15b exposed in the planarization step described with reference to FIG. 6 is selectively removed with respect to the blocking layer 40, the gap fill oxide layer 30, and the semiconductor substrate 10 using wet or dry etching. The channel area definition pattern 15b formed of the silicon nitride layer may be wet etched using a phosphoric acid strip. Thus, the opening 45 is formed in the position of the channel area definition pattern 15b, and the portion of the surface of the substrate 10 below the opening 45, i.e., the portion of the surface of the active area 20, is exposed.

As shown in FIG. 17, a spacer 85 is formed of a silicon nitride layer at an inner wall of the opening 45. The active area 20 is etched using the spacer 85, the blocking layer 40, and the gap fill oxide layer 30 as etching masks to define a portion to be used as the fin channel. The use of the spacer 85 allows the width of the fin to be adjusted. The spacer 85 is removed, and subsequent processes are performed with reference to the first embodiment.

Experimental Example

A pull-up p-channel FinFET and a pull-down n-channel FinFET of a 122M-SRAM were fabricated using the present invention. A gate insulating layer was formed of a 2 nm-silicon oxide layer, and a gate electrode was formed of a TiN/W gate electrode. For the comparison with the pull-up p-channel and pull-down n-channel FinFETs, a conventional FinFET having a polysilicon gate electrode and a conventional planar MOSFET having a polysilicon gate electrode were fabricated. The conventional FinFET and the conventional planar MOSFET have silicon oxide layers as gate insulating layers and cobalt silicide as a source and a drain.

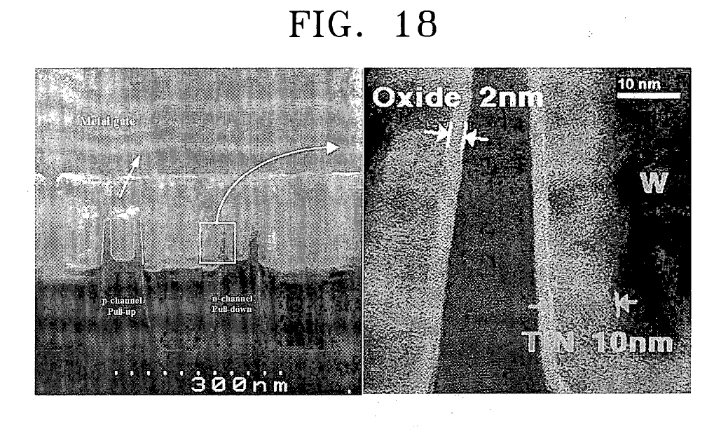

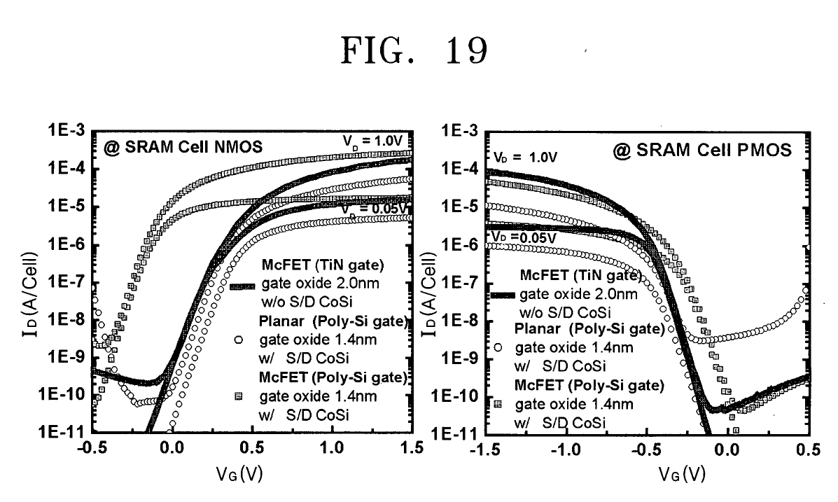

FIG. 18 shows an SEM image and a TEM image of a FinFET SRAM cell transistor having a 65 nm-TiN/W gate electrode. As shown in FIG. 18, a 10 nm-TiN layer is uniformly deposited on a 2 nm-gate oxide layer.

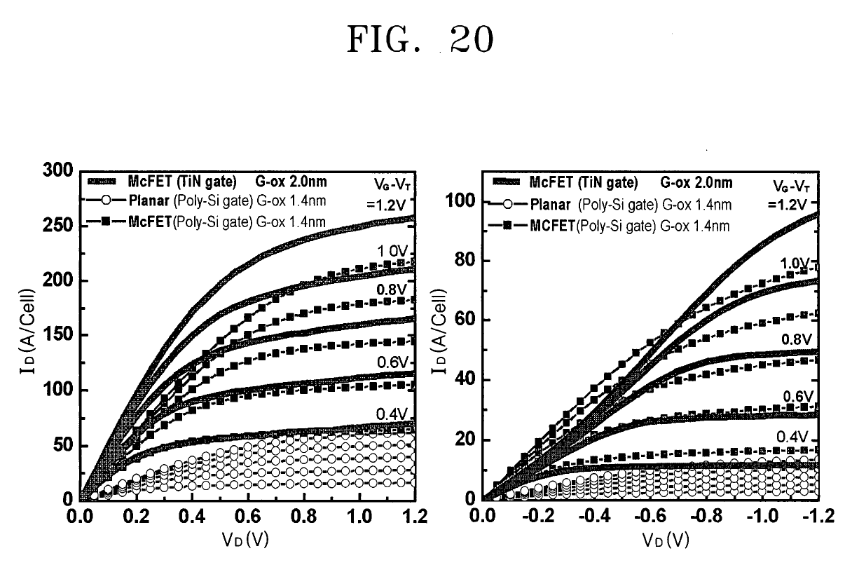

FIG. 19 is a graph showing drain currents ID and gate voltages V_{G} of a FinFET having a TIN/W electrode according to the present invention, a conventional FinFET having a polysilicon gate electrode, and a conventional planar MOSFET having a polysilicon gate electrode. The left side of the graph in FIG. 19 relates to an n-channel transistor, and the right side of the graph in FIG. 19 relates to a p-channel transistor. Solid lines in the graph denote the results of the FinFET having the TiN/W gate electrode according to the present invention, circles “∘”denote the results of the conventional FinFET having the polysilicon gate electrode, squares “□”denote the results of the conventional planar MOSFET having the polysilicon gate electrode. Since a work function of the TiN layer is a mid-gap, the TiN layer matches well with a silicon body (a semiconductor substrate). In the case of an n-channel, a threshold voltage of the FinFET having the TiN gate electrode is increased by 450 mV compared to the conventional FinFET having the polysilicon gate electrode. In the case of a p-channel, the threshold voltage of the FinFET having the TiN gate electrode is increased by 200 mV compared to the conventional FinFET having the polysilicon gate electrode. These are numerical values appropriate for operating a CMOS under 1.0 V.

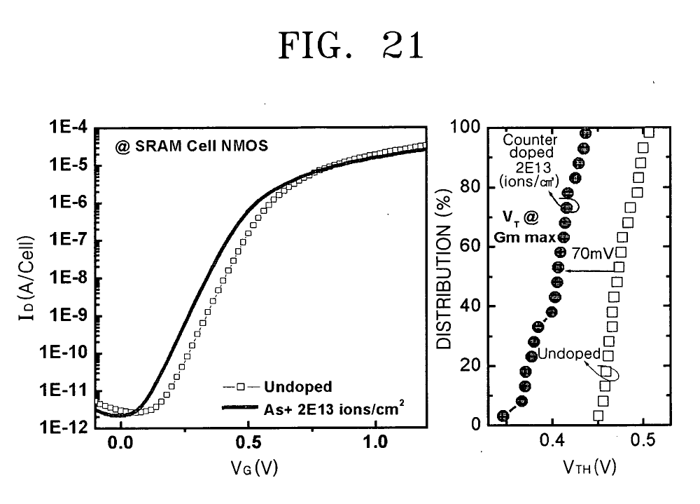

As shown in FIG. 20, since the FinFET according to the present invention uses a TiN/W metal gate electrode, a driving current of the FinFET (marked with solid lines) is higher than a driving current of the conventional FinFET (marked with “□”) using the polysilicon gate electrode and several times higher than a driving current of the conventional planar MOSFET (marked with “∘”) using the polysilicon gate electrode.

A FinFET in which counter doping is performed on an upper portion of a fin is inspected to verify an adjustment of a threshold voltage through ion implantation. As shown in FIG. 21, solid lines and circles denote the results of performing counter doping, and squares denote the results of not performing the counter doping. The upper portion of the fin is doped with ions of 2E13/cm². Thus, the threshold voltage is shifted by 70 mV without degrading the uniformity of the threshold voltage.

As a result of a test, a static noise margin is appropriate, i.e., 310 mV at a voltage of 0.8V. Also, the life span of the FinFET is secured for more than 10 years at a voltage of 2.1 V.

As described above, in a semiconductor device including a FinFET having a metal gate electrode and a fabricating method thereof according to the present invention, a central trench can be formed in an active area to form a 3-dimensional channel. Thus, a contact area between a source and a drain can be prevented from being reduced. That is, the 3-dimensional channel can be formed without reducing the area of the active area defined when an isolation area is formed.

An active area hard mask can be isotropically etched to define the channel. Thus, a process of coating or depositing an additional material for forming a channel area definition pattern can be omitted. As a result, the whole process can be simplified, and fabricating cost can be reduced.

A bulk silicon substrate can be used. Thus, compared to an SOI, fabricating unit cost can be low. Also, problems, such as a floating body effect possible in an SOI MOSFET device, a decrease in a breakdown voltage between a drain and a source, and an increase in an off-leakage current, do not occur.

Accordingly, a 65 nm-CMOS FinFET SRAM cell transistor can be fabricated according to the present invention and show an appropriate threshold voltage, subthreshold swing, and drain induced barrier lowering (DIBL). Also, a device having a static noise margin of 350 mV can be fabricated.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
an active area formed in a semiconductor substrate and protruding from a surface of the semiconductor substrate;
a fin comprising first and second protrusions formed at a surface of the active area and parallel with each other based on a central trench formed in the active area and using upper surfaces and sides of the first and second protrusions as a channel area;
a gate insulating layer formed on the active area comprising the fin;
a metal gate electrode formed on the gate insulating layer;
a gate spacer formed on a sidewall of the metal gate electrode; and
a source and a drain formed in the active area beside both sides of the metal gate electrode,
wherein the metal gate electrode comprises a barrier layer contacting the gate spacer and the gate insulating layer and a metal layer formed on the barrier layer.

2. The semiconductor device of claim 1, wherein the barrier layer is a TiN layer, and the metal layer is a W layer.

3. The semiconductor device of claim 1, wherein channel ions are implanted into a lower portion of the fin, and impurities having an opposite conductivity type to that of impurities of the channel ions are implanted into an upper portion of the fin.

4. A method of fabricating a semiconductor device, comprising:
defining an active area protruding from a surface of a semiconductor substrate;
etching a central portion of the active area to form a central trench so as to form a fin comprising first and second protrusions formed of a surface of the active area and parallel with each other based on the central trench and using upper surfaces and sides of the first and second protrusions as a channel area;
forming a gate insulating layer on the active area comprising the fin;
forming a dummy gate electrode on the gate insulating layer;
forming a gate spacer on a sidewall of the dummy gate electrode;
forming a source and a drain in the active area beside both sides of the dummy gate electrode;
depositing and planarizing an insulating layer on the semiconductor substrate so as to expose an upper surface of the dummy gate electrode;
removing the dummy gate electrode; and
forming a metal gate electrode in an area in which the dummy gate electrode is removed.

5. The method of claim 4, further comprising removing the dummy gate electrode to form a second gate insulating layer in an area in which the dummy gate electrode is removed.

6. The method of claim 4, wherein the insulating layer is deposited and planarized on the semiconductor substrate so as to expose the upper surface of the dummy gate electrode using chemical mechanical polishing.

7. The method of claim 4, wherein the insulating layer is an oxide layer deposited using high density plasma-chemical vapor deposition.

8. The method of claim 4, wherein forming the metal gate electrode comprises:
forming a barrier layer contacting the gate spacer and the gate insulating layer;
forming a metal layer on the barrier layer; and
planarizing the barrier layer and the metal layer.

9. The method of claim 8, wherein the barrier layer is a TiN layer, and the metal layer is a W layer.

10. The method of claim 8, wherein the barrier layer and the metal layer are planarized using chemical mechanical polishing.

11. The method of claim 4, wherein the metal gate electrode has an identical width to or a greater width than a width of the central trench and covers the upper surfaces and the sides of the first and second protrusions.

12. The method of claim 4, wherein a width of a contact area formed in the source and the drain is greater than the width of the metal gate electrode.

13. The method of claim 4, after defining the active area, further comprising:
performing channel ion implantation with respect to a lower portion of the active area; and
implanting impurities having an opposite conductivity type to that of impurities of the channel ion implantation into an upper portion of the active area.

14. A method of fabricating a semiconductor device, comprising:
forming an active area hard mask on a semiconductor substrate;
etching the semiconductor substrate using the active area hard mask as an etching mask to define an active area protruding from a surface of the semiconductor substrate and to form a trench surrounding the active area;
isotropic etching the active area hard mask to form a hard mask pattern exposing an edge of the active area;
filling the trench with a gap fill oxide layer and planarizing the gap fill oxide layer using the hard mask pattern as a planarization ending point;
patterning the gap fill oxide layer and the hard mask pattern in a line type to form a dummy pattern comprising at least one channel area definition pattern in the center;
depositing a blocking layer on the dummy pattern and planarizing the blocking layer using the channel area definition pattern as a planarization ending point;
removing the channel area definition pattern exposed during the planarization of the blocking layer to form an opening exposing a surface of the active area;
etching the active area below the opening to form a central trench in a portion to be used as fin channel;
recessing the blocking layer and the gap fill oxide layer to form an isolation layer around the exposed portion of the active area and exposing a fin comprising first and second protrusions formed of a surface of the semiconductor substrate between the central trench and the isolation layer and parallel with each other based on the central trench and using upper surfaces and sides of the first and second protrusions;
forming a gate insulating layer on the active area comprising the fin;
forming a dummy gate electrode on the gate insulating layer;
forming a gate spacer on a sidewall of the dummy gate electrode;
forming a source and a drain in the active area beside both sides of the dummy gate electrode;
depositing and planarizing an insulating layer on the semiconductor substrate to expose an upper surface of the dummy gate electrode;
removing the dummy gate electrode; and
forming a metal gate electrode in an area in which the dummy gate electrode is removed.

15. The method of claim 14, after removing the dummy gate electrode, further comprising:
forming a second gate insulating layer in an area in which the dummy gate electrode is removed.

16. The method of claim 14, wherein the insulating layer is deposited and planarized on the semiconductor substrate so as to expose the upper surface of the dummy gate electrode using chemical mechanical polishing.

17. The method of claim 14, wherein the insulating layer is an oxide layer deposited using high density plasma-chemical vapor deposition.

18. The method of claim 14, wherein forming the metal gate electrode comprises:
forming a barrier layer contacting the gate spacer and the gate insulating layer;
forming a metal layer on the barrier layer; and
planarizing the barrier layer and the metal layer.

19. The method of claim 18, wherein the barrier layer is a TiN layer, and the metal layer is a W layer.

20. The method of claim 18, wherein the barrier layer and the metal layer are planarized using chemical mechanical polishing.

21. The method of claim 14, wherein the metal gate electrode has an identical width to or a greater width than a width of the central trench and covers the upper surfaces and the sides of the first and second protrusions.

22. The method of claim 14, wherein a width of a contact area formed in the source and the drain is greater than the width of the metal gate electrode.

23. The method of claim 14, after defining the active area, further comprising:
performing channel ion implantation with respect to a lower portion of the active area; and
implanting impurities having an opposite conductivity type to that of impurities of the channel ion implantation into an upper portion of the active area.

24. The method of claim 14, wherein the active area hard mask is formed of a silicon nitride layer, and the isotropic etching is wet etching using phosphoric acid (H₃PO₄).

25. The method of claim 14, wherein the isotropic etching is wet etching or dry etching using plasma.

26. The method of claim 14, wherein a width of the fin is adjusted by adjusting a time required for the isotropic etching.

27. The method of claim 14, wherein the gap fill oxide layer is planarized using chemical mechanical polishing or blanket etching.

28. The method of claim 14, wherein the blocking layer is formed of a silicon oxide layer.

29. The method of claim 14, wherein the blocking layer is planarized using chemical mechanical polishing or blanket etching.

30. The method of claim 14, wherein the gate insulating layer is formed by growing a silicon oxide layer using a thermal oxidation method or by depositing or coating one of a silicon oxide layer, a hafnium oxide layer, a zirconium oxide layer, an aluminum oxide layer, a silicon nitride layer, and a silicon oxide nitride layer using one of atomic layer depositing, chemical vapor deposition, plasma enhanced-atomic layer deposition, and plasma enhanced-chemical vapor deposition.

31. The method of claim 14, wherein the blocking layer and the gap fill oxide layer are recessed to a same height as a bottom of the central trench.

32. The method of claim 14, wherein the blocking layer and the gap fill oxide layer are recessed higher than the bottom of the central trench.

33. The method of claim 14, after the opening is formed, further comprising:
forming a spacer on an inner wall of the opening,
wherein the spacer is used for forming the central trench and then removed.

34. The method of claim 14, wherein the spacer is formed of a silicon nitride layer.
